(19) United States
(12) Patent Application Publication
(10) Pub. No.: US 2014/0061908 A1
(43) Pub. Date: Mar. 6, 2014

(54) PLASTIC BALL GRID ARRAY PACKAGE HAVING REINFORCEMENT RESIN

(71) Applicant: SIGNETICS KOREA CO., LTD, Gyeonggi-do (KR)

(72) Inventors: Hyo Jae YEE, Gyeonggi-do (KR); Chang Young LEE, Gyeonggi-do (KR); Myun Soo KIM, Gyeonggi-do (KR)

(73) Assignee: SIGNETICS KOREA CO., LTD, Gyeonggi-do (KR)

(21) Appl. No.: 14/020,272

(22) Filed: Sep. 6, 2013

(30) Foreign Application Priority Data
Sep. 6, 2012 (KR) 10-2012-0098851

(51) Int. Cl. H01L 23/00

(52) U.S. Cl. CPC H01L 24/14
USPC 257/738

(57) ABSTRACT

A plastic ball grid array package having a reinforcement resin that may address the problem of delamination and cracks in a boundary region between a sealing resin and a substrate. The reinforcement resin is formed at an outer region of a sealing resin and has a height that is lower than that of the sealing resin. The reinforcement resin may be formed of the same material used to form the sealing resin and has a structure completely covering a first surface of the substrate. Accordingly, cracks and delamination defects of the semiconductor package may be reduced by absorbing stress that occurs by physical impact in a boundary region between the substrate and the sealing resin.

### CROSS-REFERENCE TO RELATED PATENT APPLICATION

This application claims the benefit of Korean Patent Application No. 10-2012-0098851, filed on Sep. 6, 2012, in the Korean Intellectual Property Office, the disclosure of which is incorporated herein in its entirety by reference.

### BACKGROUND

The disclosed embodiment relates to a semiconductor package, and more particularly, to a plastic ball grid array package that includes a resin that surrounds a semiconductor chip to protect it and includes a conductive material, such as a solder ball, as an external connection terminal.

In the related arts, leads are mainly used for connecting a semiconductor package to the outside. However, as the capacity of the semiconductor packages is increased and the function of the semiconductor chips is diversified, many input/output terminals are needed in a single semiconductor package. However, when leads are used as the input/output terminals, there is a difficulty increasing the number of input/output terminals because the number of leads that may be disposed in a unit area is limited. In order to address this problem, a semiconductor package, in which a greater number of input/output terminals may be designed, has been developed. The semiconductor package, instead of the leads, uses solder balls as the input/output terminals for external connecting terminals to the outside. A representative semiconductor package that uses solder balls as the external connecting terminals is a plastic ball grid array (PBGA) package.

### SUMMARY

The disclosed embodiment provides a plastic ball grid array (PBGA) package having a reinforcement resin that may increase an overall reliability thereof by reducing a crack defect of a printed circuit board due to stress in a boundary region between the printed circuit board and a sealing resin, or a delamination defect between the printed circuit board and the sealing resin.

According to an aspect of the disclosed embodiment, there is provided a plastic ball grid array package having reinforcement resin, comprising: a substrate that is used as a basic frame for a semiconductor package; a semiconductor chip mounted on a first surface of the substrate; conductive wirings that connect the substrate and the semiconductor chip to each other; a sealing resin that is formed on the first surface of the substrate to surround the semiconductor chip and the conductive wirings; a reinforcement resin that is formed at an outer region of the sealing resin and has a height that is lower than that of the sealing resin; and external connecting terminals attached to a second surface of the substrate.

The height of the reinforcement resin may be within a range from about 10% to about 95% of the height of the sealing resin.

The reinforcement resin may be the same material as the sealing resin, and may be an epoxy mold compound (EMC)

The reinforcement resin may cover the rest of the region of the first surface of the substrate that is covered by the sealing resin.

The plastic ball grid array package may further include a heat radiation element that covers the semiconductor chip and the conductive wirings and that is exposed through the sealing resin to the outside.

The substrate may include vias through which printed circuit patterns of the first surface of the substrate extend to the second surface of the substrate.

Some of the vias may be formed at an outer region of the sealing resin.

The conductive wirings may be one selected from the group consisting of wires and bumps.

First, according to the current embodiment, since the reinforcement resin is additionally formed on an outer region of the sealing resin, the reinforcement resin may absorb stress that may occur in a boundary region between the sealing resin and the printed circuit substrate, that is, the substrate. Accordingly, the problem of crack and delamination defect caused by the stress may be prevented by the function of the reinforcement resin.

Second, according to the current embodiment, since the reinforcement resin additionally covers on a region of the second surface of the substrate where solder masks are formed, the solder masks are not exposed to the outside, and thus, the problem of causing scratches on the second surface of the substrate may be prevented.

Third, in a molding process of the sealing resin in a manufacturing method of the semiconductor package, in a related art, unit semiconductor packages are individually formed in a strip unit having a single row and a plurality of columns. However, in the PBGA package according to the current embodiment, individual semiconductor packages are connected to each other by the reinforcement resin, and thus, the molding process may be performed with a plurality of rows and a plurality of columns. Therefore, productivity may be increased and manufacturing costs may be reduced.

### BRIEF DESCRIPTION OF THE DRAWINGS

The above and other features and advantages of the disclosed embodiment will become more apparent by describing in detail exemplary embodiments thereof with reference to the attached drawings in which:

FIG. 1 is a cross-sectional view of a semiconductor package according to an embodiment of the disclosed embodiment;

FIG. 2 is a plan view of the semiconductor package of FIG. 1;

FIG. 3 is a cross-sectional view of a modified embodiment of the semiconductor package of FIG. 1;

FIG. 4 is a plan view of the modified embodiment of the semiconductor package of FIG. 1;

FIG. 5 is a cross-sectional view of another modified embodiment of the semiconductor package of FIG. 1; and

FIG. 6 is a block diagram showing an application of the embodiment of the disclosed embodiment.

### DETAILED DESCRIPTION

Hereafter, the disclosed embodiment will be described more fully with reference to the accompanying drawings, in which exemplary aspects of the disclosed embodiment are shown. The disclosed embodiment may, however, be embodied in many different forms and should not construed as limited to the exemplary aspects set forth herein. Rather, these aspects are provided so that this disclosure will be thorough and complete, and will fully convey the scope of the disclosed embodiment to those of ordinary skill in the art. In the drawings, for convenience of explanation, constituent elements may be enlarged and ratios between the constituent elements may be reduced or exaggerated.

It will be understood that, although the terms “first”, “second”, etc. may be used herein to describe various elements, these elements should not be limited by these terms. These terms are only used to distinguish one element from another. For example, a first element could be termed a second element and a second element could be termed a first element without departing from the teachings of the present inventive concept.

As used herein, the singular forms include the plural forms as well, unless the context clearly indicates otherwise. It will be further understood that the terms “comprises”, “comprising”, “includes”, and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which the disclosed embodiment belongs. It will be further understood that terms, such as those defined in commonly used in dictionaries, should be interpreted as having a meaning that is consistent with their meaning in the context of the relevant art and will not be interpreted in an idealized or overly formal senses unless expressly so defined herein.

Hereafter, the disclosed embodiment will be described more fully with reference to the accompanying drawings, in which exemplary aspects of the disclosed embodiment are shown. In the drawings, like reference numerals denote like elements.

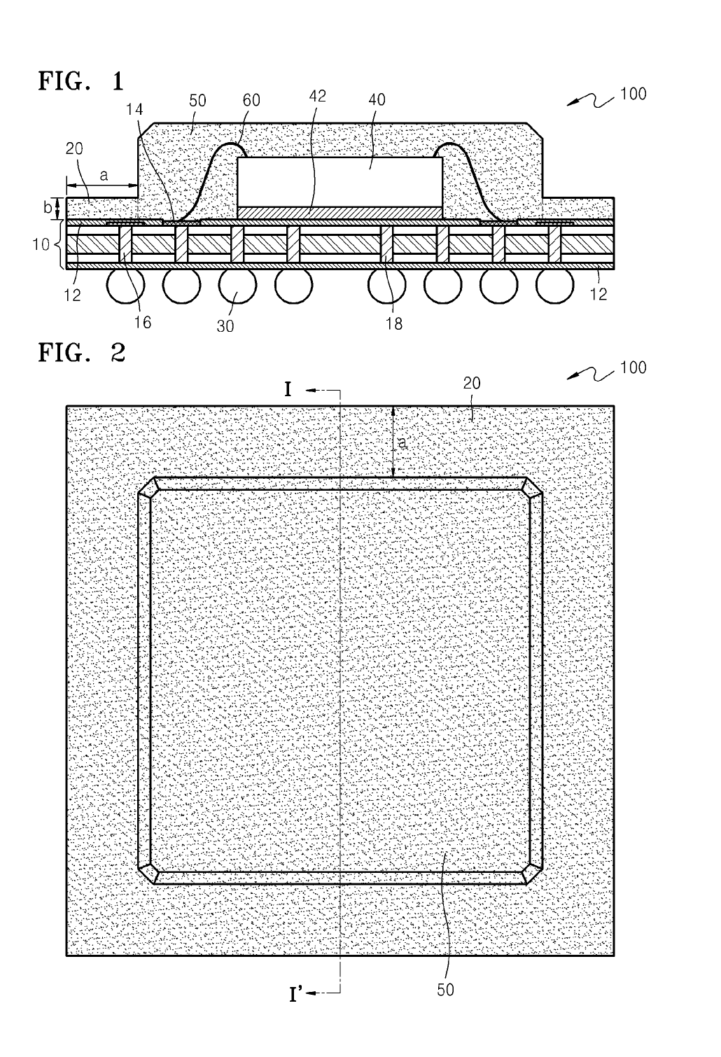

FIG. 1 is a cross-sectional view of a plastic ball grid array (PBGA) package 100 having reinforcement resin, according to an aspect of the disclosed embodiment. FIG. 2 is a plan view of the PBGA package 100 of FIG. 1. FIG. 1 is a cross-sectional view taken along line I-I′ of FIG. 2.

Referring to FIGS. 1 and 2, the PBGA package 100 having a reinforcement resin according to an aspect of the disclosed embodiment includes a substrate 10 that is used as a basic frame for a semiconductor package. The substrate 10 may be a rigid-type printed circuit board (PCB). In FIG. 1, the substrate 10 is a PCB formed of three layers including a conductive layer and insulating layers. However, the substrate 10 may be a multi-layer substrate having two layers or more.

The substrate 10 may include a solder mask 12, bond fingers 14, and various types of printed circuit patterns on a front surface, that is, a first surface, thereof, and also, may include a solder mask 12 and solder ball pads on a bottom surface, that is, a second surface, thereof. The substrate 10 may include vias 16 and 18 through which the printed circuit patterns of the first surface may extend to the second surface. At this point, some the vias 16 may be formed at an outer region of a sealing resin 50. A reference number 18 indicates the via formed at an inner side of the sealing resin 50.

The PBGA package 100 having a reinforcement resin according to an aspect of the disclosed embodiment includes a semiconductor chip 40 mounted on the first surface of the substrate 10 and conductive wirings 60 that connect the substrate 10 and the semiconductor chip 40. The semiconductor chip 40 may be attached to a chip mounting unit of the substrate 10 by using an epoxy or die attach film (DAF) 42. The conductive wirings 60 are depicted as wires as an example, but may be any method that may electrically connect the semiconductor chip 40 and the substrate 10.

The PBGA package 100 having a reinforcement resin may include the sealing resin 50 that surrounds the semiconductor chip 40 and the conductive wirings 60 on the first surface of the substrate 10 and a reinforcement resin 20 that is formed at an outer region of the sealing resin 50 and has a height b (refer to FIG. 1) that is lower than that of the sealing resin 50. The sealing resin 50 and the reinforcement resin 20 may be formed of the same material, for example, epoxy mold compound (EMC). Also, the sealing resin 50 and the reinforcement resin 20 may not be formed through a separate process, but may be formed in a single molding process.

The reinforcement resin 20 may cover a portion of the first surface of the substrate 10, wherein the portion is not covered by the sealing resin 50 (refer to FIG. 1). However, although the reinforcement resin 20 does not cover the whole remaining portion of the first surface of the substrate 10, the reliability effect of the PBGA package 100 may be achieved to some degree. The reinforcement resin 20 may be formed to have a height within a range from about 10% to about 95% of the height of the sealing resin 50.

Thus, the reinforcement resin 20 prevents the occurrence of process defects, such as cracks or delamination, in the first surface of the substrate 10, by absorbing stress generated in a boundary region between the sealing resin 50 and the substrate 10. Accordingly, the reliability of the PBGA package 100 may be increased. The process defects, such as cracks or delamination, may further severely occur when the vias 16 of the substrate 10 are formed at an outer region of the sealing resin 50. In the current embodiment, the process defects may be addressed through the reinforcement resin 20.

The reinforcement resin 20 is formed to cover the solder mask 12 that is exposed on the first surface of the substrate 10. Accordingly, a problem of causing scratches or damage to the solder mask 12 in a process or handling may be prevented.

The PBGA package 100 having a reinforcement resin, according to an aspect of the disclosed embodiment, includes external connecting terminals 30 attached to the second surface of the substrate 10. In FIG. 1, as an example, the external connecting terminals 30 are depicted as solder balls. However, the external connecting terminals 30 may be of a land type having a reduced height, or may be any shape as long as the external connecting terminals 30 may electrically connect the substrate 10 and the main PCB on which the PBGA package 100 is mounted.

A method of manufacturing the PBGA package 100 having a reinforcement resin is as follows: First, the substrate 10 is prepared, and the semiconductor chip 40 is attached to the substrate 10 by using an epoxy or a DAF 42. Next, a bond pad of the semiconductor chip 40 is electrically connected to the bond finger 14 of the substrate 10 via the conductive wirings 60, for example, wires. The sealing resin 50 and the reinforcement resin 20 are formed by a single molding process using the same material. Afterwards, the external connecting terminals 30, such as solder balls, are attached to the second surface of the substrate 10, and a matrix-type substrate having a plurality of rows and columns is cut using a blade.

Here, if the reinforcement resin 20 is not formed, a strip-type substrate having a single row and a plurality of columns is used. However, according to the current embodiment, since the reinforcement resin 20 is additionally formed in manufacturing the PBGA package 100, the PBGA package 100 may be manufactured by using a matrix-type substrate having a plurality of rows and columns. Thus, productivity may be increased and a cost reduction may be achieved in a semiconductor package manufacturing method.

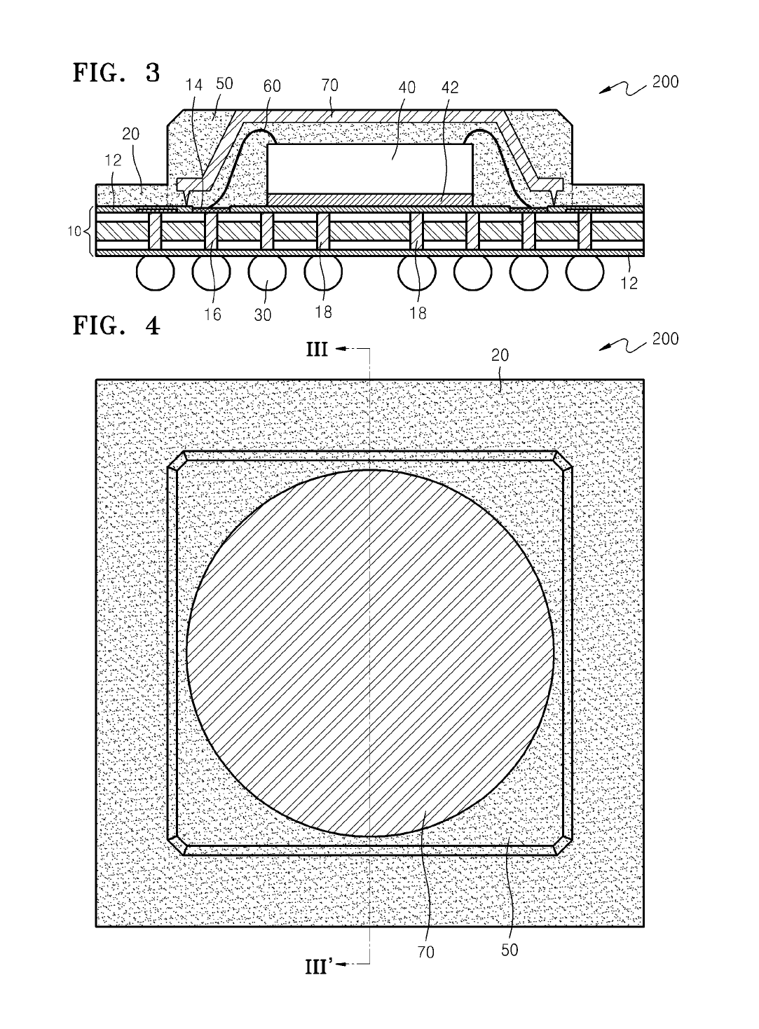

FIG. 3 is a cross-sectional view of a modified embodiment of the semiconductor package of FIG. 1. FIG. 4 is a plan view of the modified embodiment of the semiconductor package of FIG. 1. FIG. 3 is a cross-sectional view taken along line III-III′ of FIG. 4.

Referring to FIGS. 3 and 4, a PBGA package 200 having a reinforcement resin includes the substrate 10, the semiconductor chip 40, the conductive wirings 60, the sealing resin 50, the reinforcement resin 20, and the external connecting terminals 30, like the PBGA package 100 having a reinforcement resin described with reference to FIGS. 1 and 2, and also, additionally includes a heat radiation plate 70 in the sealing resin 50.

The heat radiation plate 70 may be designed to be exposed to the outside to effectively dissipate heat generated from the semiconductor chip 40. At this point, the material and shape of the heat radiation plate 70 may be appropriately selected.

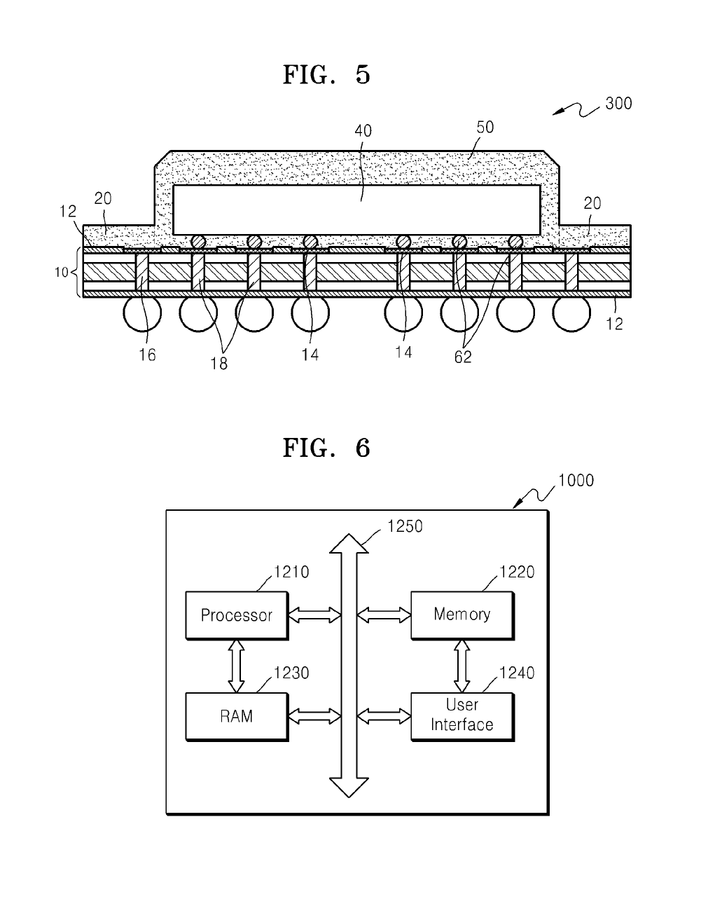

FIG. 5 is a cross-sectional view of another modified embodiment of the semiconductor package of FIG. 1.

Referring to FIG. 5, in a PBGA package 300 having a reinforcement resin, bumps 62 are used as conductive wirings for electrically connecting the semiconductor chip 40 and the substrate 10, unlike in the PBGA package 100 of FIG. 1, in which wires are used as the conductive wirings 60. Accordingly, the DAF is unnecessary. Also, if necessary, an underfill may be additionally formed on regions where the bumps 62 are formed between the substrate 10 and the semiconductor chip 40.

The rest of the configuration of the PBGA package 300 is similar to the PBGA packages 100 and 200 of FIGS. 1 and 3, and thus, descriptions thereof are not repeated.

FIG. 6 is a block diagram showing an application of the disclosed embodiment.

Referring to FIG. 6, an electronic system 1000 may include at least one of the PBGA packages 100, 200, and 300 having a reinforcement resin, which are described with reference to FIGS. 1 through 5. The electronic system 1000 may be applied to mobile devices or computers. For example, the electronic system 1000 may include a processor 1210, a memory system 1220, RAM 1230, and a user interface 1240 that may communicate via a bus 1250. The processor 1210 may execute a program and may control the electronic system 1000. The RAM 1230 may be used as a driving memory of the processor 1210. Here, a semiconductor package that is used as the processor 1210, the memory system 1220, the RAM 1230, and the user interface 1240 may have the structure of the PBGA packages 100, 200, and 300 having a reinforcement resin. Since the reliability of each of the semiconductor packages that constitute the electronic system 1000 is increased, the electronic system 1000 may have a low defect rate.

The user interface 1240 may be used for inputting or outputting data to or from the electronic system 1000. The memory system 1220 may store a code for operating the processor 1210, data processed by the processor 1210, or data inputted from the outside. The memory system 1220 may include a controller and a memory. The electronic system 1000 that is described above may be applied to an electronic control device of various electronic devices. The electronic system 1000 of FIG. 6 may also be applied to mobile game consoles, mobile notebooks, MP3 players, navigation devices, solid state discs (SSDs), automobiles, or household appliances.

While the disclosed embodiment has been particularly shown and described with reference to exemplary embodiments thereof, it will be understood by those of ordinary skill in the art that various changes in form and details may be made therein without departing from the spirit and scope of the disclosed embodiment as defined by the following claims.

1. A plastic ball grid array package having reinforcement resin, comprising:
a substrate that is used as a basic frame for a semiconductor package;
a semiconductor chip mounted on a first surface of the substrate;
conductive wirings that connect the substrate and the semiconductor chip to each other;
a sealing resin that is formed on the first surface of the substrate to surround the semiconductor chip and the conductive wirings;
a reinforcement resin that is formed at an outer region of the sealing resin and has a height that is lower than that of the sealing resin; and
external connecting terminals attached to a second surface of the substrate.

2. The plastic ball grid array package of claim 1, wherein the height of the reinforcement resin is within a range from about 10% to about 95% of the height of the sealing resin.

3. The plastic ball grid array package of claim 1, wherein the reinforcement resin is the same material as the sealing resin, and is an epoxy mold compound (EMC).

4. The plastic ball grid array package of claim 1, wherein the reinforcement resin covers the rest of the region of the first surface of the substrate that is covered by the sealing resin.

5. The plastic ball grid array package of claim 1, further comprising a heat radiation element that covers the semiconductor chip and the conductive wirings and that is exposed through the sealing resin to the outside.

6. The plastic ball grid array package of claim 1, wherein the substrate comprises vias through which printed circuit patterns of the first surface of the substrate extend to the second surface of the substrate.

7. The plastic ball grid array package of claim 6, wherein some of the vias are formed at an outer region of the sealing resin.

8. The plastic ball grid array package of claim 1, wherein the conductive wirings are one selected from the group consisting of wires and bumps.
